(19) United States
(12) Patent Application Publication
(10) Pub. No.: US 2017/0311439 A1
(43) Pub. Date: Oct. 26, 2017

(54) PRINTED CIRCUIT BOARD WITH ENHANCED IMMUNITY TO SIMULTANEOUS SWITCHING NOISE

(71) Applicant: HON HAI PRECISION INDUSTRY CO., LTD., New Taipei (TW)

(72) Inventor: SHAO-YOU TANG, New Taipei (TW)

(21) Appl. No.: 15/191,968

(22) Filed: Jun. 24, 2016

(30) Foreign Application Priority Data
Apr. 26, 2016 (CN) 201610263150.0

(51) Int. Cl. H05K 1/02; H05K 1/16; H05K 1/11

(52) U.S. Cl. CPC H05K 1/0233; H05K 1/165; H05K 1/0236; H05K 1/115; H05K 1/162

(57) ABSTRACT

A printed circuit board including a series-wound inductor and two capacitors to reduce the susceptibility of a printed circuit board to simultaneous switching noise includes a ground layer; a power layer defining a slot loop to isolate a metal plate within, and a via hole coupled between the metal plate and the ground layer. An electronic device with the printed circuit board is also disclosed.

### FIELD

The subject matter herein generally relates to a printed circuit board having a simultaneous switching noise (SSN) filtering circuit layout.

### BACKGROUND

In a circuit layout, a via hole is configured to couple signal lines between different layers. When a signal current flows through each via hole, an inverse current may be discontinuous in a corner between adjacent different layers. The discontinuous inverse current will flow in the circuit board in a manner of displacement current and electromagnetic noise is thus generated in the circuit, the electromagnetic noise is called SSN.

### BRIEF DESCRIPTION OF THE DRAWINGS

Implementations of the present technology will now be described, by way of example only, with reference to the attached figures.

FIG. 1 is an assembled, view of an embodiment of an electronic device with a printed circuit board.

FIG. 2 is a schematic view of the printed circuit board of FIG. 1.

FIG. 3 is similar to FIG. 2, but viewed from a different angle.

FIG. 4 is side view of the printed circuit board of FIG. 2.

FIG. 5 is an equivalent lumped circuit of an electromagnetic band-gap of the circuit board of FIG. 2.

FIG. 6 is a simulation comparison view of current printed circuit board and a previous printed circuit board.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

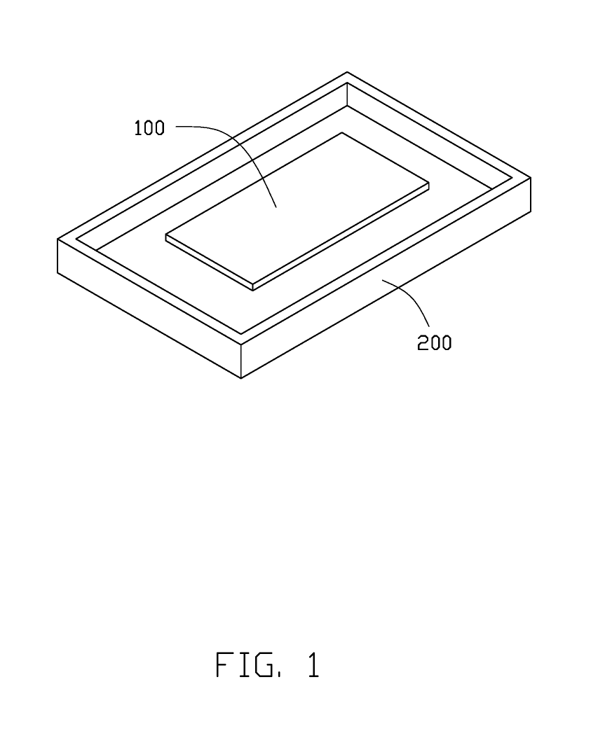

FIG. 1 illustrates a printed circuit board 100 in an embodiment, mounted in an electronic device 200. In at least one embodiment, the printed circuit board 100 is a motherboard, and the electronic device 200 is a computer.

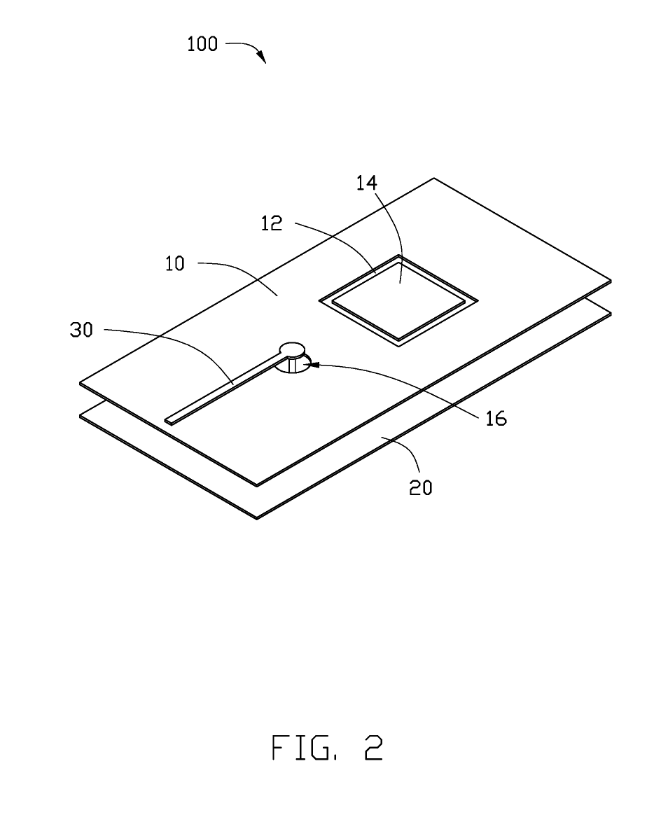

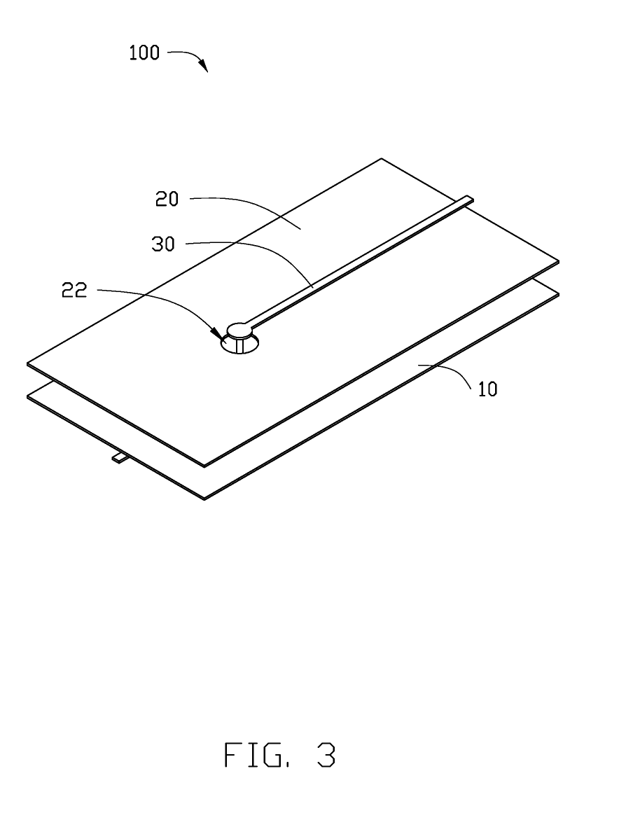

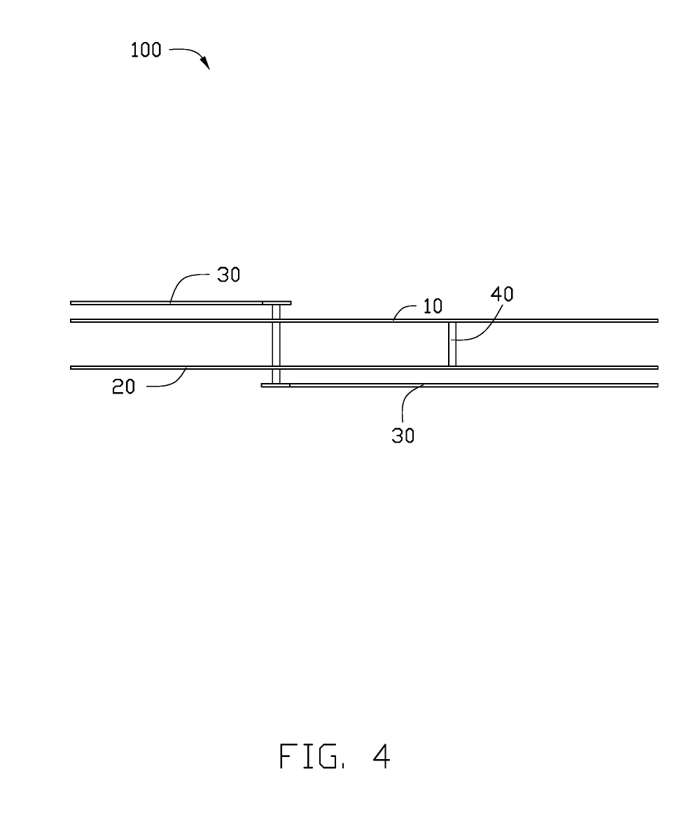

FIGS. 2-4 illustrate that the printed circuit board 100 can include a power layer 10, a grounded layer 20, a signal line 30, and a via hole 40.

The power layer 10 defines a slot loop 12 to create a separation from a metal plate 14 within the slot loop 12. In at least one embodiment, the slot loop 12 is substantially rectangular.

In at least one embodiment, the metal plate 14 is substantially rectangular.

A top surface of the metal plate 14 is coplanar with a top surface of the power layer 10.

A bottom surface of the metal plate 14 is coplanar with a bottom surface of the power layer 10.

The power layer 10 defines a first through hole 16. The grounded layer 20 defines a second through hole 22 aligned with the first through hole 16. The signal line 30 can pass through the power layer 10 and the grounded layer 20 via the first through hole 16 and the second through hole 22.

The via hole 40 couples the metal plate 14 and the grounded layer 20. The via hole 40 can generate inductance.

A different potential between the metal plate 14 and the power layer 10 will cause a plurality of charge to accumulate around the metal plate 14. A capacitance effect will exist around the metal plate 14 and the power layer 10.

The series-wound inductance and capacity has a low impedance characteristic similar to that of a short circuit under a resonant frequency, which can resist noise in the power layer 10 and the grounded layer 20.

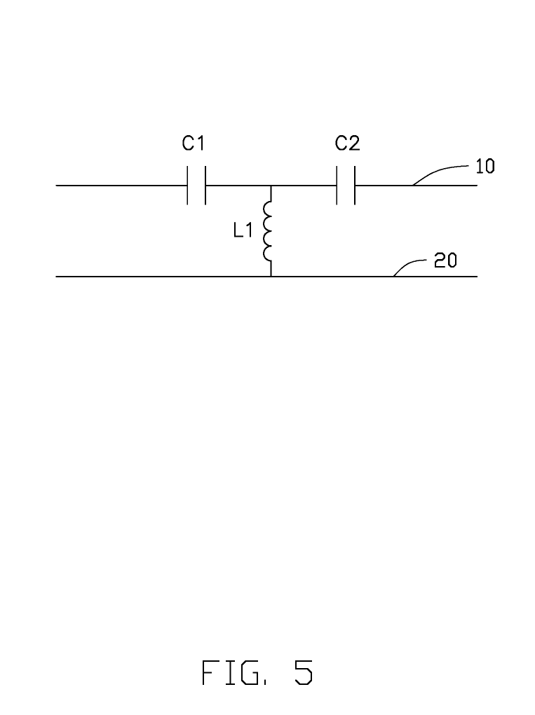

FIG. 5 illustrates that an equivalent lumped circuit of an electromagnetic band-gap structure is formed by the metal plate 14, the grounded layer 20, and the via hole 40.

In the equivalent circuit, the capacitor C1 is coupled to the inductance L1 in series to create a first series-wound circuit. The capacitor C2 is coupled to the inductance L1 in series to create a second series-wound circuit coupled to the capacity C1 in parallel.

Each of the first series-wound circuit and the second series-wound circuit will be shorted under a certain resonant frequency, such that noise in the power layer 10 and the grounded layer 20 can be reduced.

In addition, the electromagnetic band-gap structure can restrict an extension of frequency band of noise, which can achieve a better effect in reducing noise.

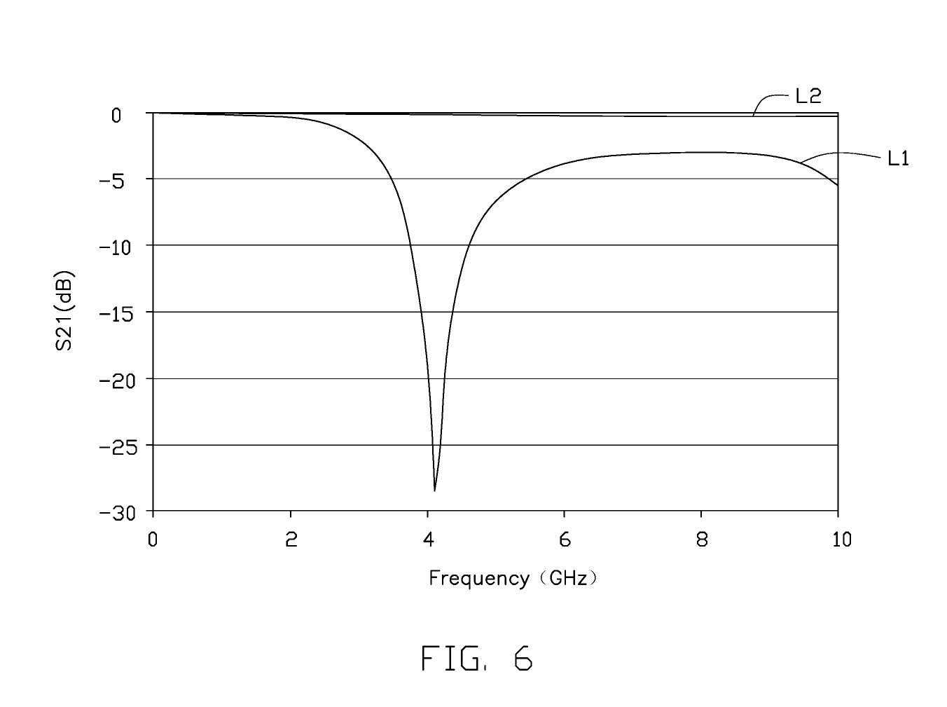

FIG. 6 illustrates that the current electromagnetic band-gap structure (L1) has a larger forbidden band in comparison with a previous electromagnetic band-gap structure (L2).

When the frequency is 4 GHz, the electromagnetic band-gap structure (L1) has a better noise restraining feature.

The resonant frequency of the equivalent lumped circuit of the electromagnetic band-gap structure can be changed to follow a change in the diameter of the via hole 40 and a change in the area of the metal plate 14.

A change in the diameter of the via hole 40 and in the area of the metal plate 14 can adjust the equivalent lumped inductance and the equivalent lumped capacitance to restrain noise at different frequencies.

The embodiments shown and described above are only examples. Many details are often found in the art such as the other features of a printed circuit board with enhanced immunity to simultaneous switching noise Therefore, many such details are neither shown nor described. Even though numerous characteristics and advantages of the present technology have been set forth in the foregoing description, together with details of the structure and function of the present disclosure, the disclosure is illustrative only, and changes may be made in the details, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A printed circuit board comprising:
a grounded layer;
a power layer defining a slot loop to separate an isolated metal plate from the power layer within the slot loop; and
a via hole coupled between the metal plate and the grounded layer.

2. The printed circuit board of claim 1, further comprising a signal line, wherein the power layer defines a first through hole, the grounded layer defines a second through hole, and the signal line passes through the power layer and the grounded layer via the first through hole and the second through hole.

3. The printed circuit board of claim 2, wherein the first through hole is aligned with the second through hole.

4. The printed circuit board of claim 1, wherein the slot loop is substantially rectangular.

5. The printed circuit board of claim 1, wherein the metal plate is rectangular.

6. The printed circuit board of claim 1, wherein a metal plate top surface is coplanar with a power layer top surface.

7. The printed circuit board of claim 6, wherein a metal plate bottom surface is coplanar with a power layer bottom surface.

8. A printed circuit board comprising:
a grounded layer;
a power layer defining a slot loop to separate an isolated metal plate from the power layer within the slot loop;
a via hole coupled between the metal plate and the grounded layer; and
a signal line passing through the grounded layer and the power layer.

9. The printed circuit board of claim 8, wherein the power layer defines a first through hole, the grounded layer defines a second through hole, and the signal line passes through the power layer and the grounded layer via the first through hole and the second through hole.

10. The printed circuit board of claim 9, wherein the first through hole is aligned with the second through hole.

11. The printed circuit board of claim 8, wherein the slot loop is substantially rectangular.

12. The printed circuit board of claim 8, wherein the metal plate is rectangular.

13. The printed circuit board of claim 8, wherein a metal plate top surface is coplanar with a power layer top surface.

14. The printed circuit board of claim 13, wherein a metal plate bottom surface is coplanar with a power layer bottom surface.

15. An electronic device comprising:
a housing; and
a printed circuit board received in the housing and comprising:
a grounded layer;
a power layer defining a slot loop to separate an isolated metal plate from the power layer within the slot loop; and
a via hole coupled between the metal plate and the grounded layer.

16. The electronic device of claim 15, further comprising a signal line, wherein the power layer defines a first through hole, the grounded layer defines a second through hole, and the signal line passes through the power layer and the grounded layer via the first through hole and the second through hole.

17. The electronic device of claim 16, wherein the first through hole is aligned with the second through hole.

18. The electronic device of claim 15, wherein the slot loop is substantially rectangular, and the metal plate is rectangular.

19. The electronic device of claim 15, wherein a metal plate top surface is coplanar with a power layer top surface.

20. The electronic device of claim 19, wherein a metal plate bottom surface is coplanar with a power layer bottom surface.
